(19) United States
(12) Patent Application Publication
(10) Pub. No.: US 2019/0139920 A1
(43) Pub. Date: May 9, 2019

(54) FAN-OUT SEMICONDUCTOR PACKAGE

(71) Applicant: SAMSUNG ELECTRO-MECHANICS CO., LTD., Suwon-Si, (KR)

(72) Inventors: Doo Hwan LEE, Suwon-Si (KR); Da Hee KIM, Suwon-Si (KR)

(21) Appl. No.: 15/958,370

(22) Filed: Apr. 20, 2018

(30) Foreign Application Priority Data
Nov. 7, 2017 (KR) 10-2017-0147250

(51) Int. Cl. H01L 23/00; H01L 25/065

(52) U.S. Cl. CPC H01L 24/09; H01L 25/0657; H01L 23/3128; H01L 24/14; H01L 2924/15311; H01L 24/17

(57) ABSTRACT

A fan-out semiconductor package includes: a first structure including a first semiconductor chip, a first encapsulant encapsulating at least portions of the first semiconductor chip, and a first connection member disposed on the semiconductor chip and including a first redistribution layer electrically connected to the first connection pads; and a second structure including a second semiconductor chip, a second encapsulant encapsulating at least portions of the second semiconductor chip, and a second connection member disposed on the semiconductor chip and including a second redistribution layer electrically connected to the second connection pads. The first and second structures are disposed so that first and second active surfaces face each other, and the first and second redistribution layers are connected to each other through a low melting point metal disposed between the first and second redistribution layers.

### CROSS-REFERENCE TO RELATED APPLICATION(S)

This application claims benefit of priority to Korean Patent Application No. 10-2017-0147250 filed on Nov. 7, 2017 in the Korean Intellectual Property Office, the disclosure of which is incorporated herein by reference in its entirety.

### TECHNICAL FIELD

The present disclosure relates to a semiconductor package, and more particularly, to a fan-out semiconductor package in which electrical connection structures may extend outwardly of a region in which a semiconductor chip is disposed.

### BACKGROUND

A significant recent trend in the development of technology related to semiconductor chips has been reductions in the size of semiconductor chips. Therefore, in the field of package technology, in accordance with a rapid increase in demand for small-sized semiconductor chips, or the like, the implementation of a semiconductor package, having a compact size while including a plurality of pins, has been demanded.

One type of semiconductor package technology suggested to satisfy the technical demand, described above, is a fan-out semiconductor package. Such a fan-out package has a compact size and may allow a plurality of pins to be implemented by redistributing connection terminals outwardly of a region in which a semiconductor chip is disposed.

### SUMMARY

An aspect of the present disclosure may provide a fan-out semiconductor package capable of being thinned and miniaturized in spite of using a plurality of semiconductor chips, reducing signal loss by shortening a connection distance between chips, and having improved reliability by securing sufficient rigidity.

According to an aspect of the present disclosure, a fan-out semiconductor package may be provided, in which a plurality of semiconductor chips are disposed in a package-on-package form or a package-on-chip form, the respective semiconductor chips are disposed so that active surfaces thereof face each other, and redistribution layers redistributing the semiconductor chips are connected to each other by a low melting point metal.

According to an aspect of the present disclosure, a fan-out semiconductor package may include: a first structure including a first semiconductor chip having a first active surface having first connection pads disposed thereon and a first inactive surface opposing the first active surface, a first encapsulant encapsulating at least portions of the first semiconductor chip, and a first connection member disposed on the first active surface and including a first redistribution layer electrically connected to the first connection pads; and a second structure including a second semiconductor chip having a second active surface having second connection pads disposed thereon and a second inactive surface opposing the second active surface, a second encapsulant encapsulating at least portions of the second semiconductor chip, and a second connection member disposed on the second active surface and including a second redistribution layer electrically connected to the second connection pads. The first and second structures may be disposed so that the first and second active surfaces face each other, and the first and second redistribution layers may be connected to each other through a low melting point metal disposed between the first and second redistribution layers.

### BRIEF DESCRIPTION OF DRAWINGS

The above and other aspects, features, and advantages of the present disclosure will be more clearly understood from the following detailed description taken in conjunction with the accompanying drawings, in which:

FIG. 1 is a schematic block diagram illustrating an example of an electronic device system;

FIG. 2 is a schematic perspective view illustrating an example of an electronic device;

FIGS. 3A and 3B are schematic cross-sectional views illustrating states of a fan-in semiconductor package before and after being packaged;

FIG. 4 is schematic cross-sectional views illustrating a packaging process of a fan-in semiconductor package;

FIG. 5 is a schematic cross-sectional view illustrating a case in which a fan-in semiconductor package is mounted on a ball grid array (BGA) substrate and is ultimately mounted on a mainboard of an electronic device;

FIG. 6 is a schematic cross-sectional view illustrating a case in which a fan-in semiconductor package is embedded in a BGA substrate and is ultimately mounted on a mainboard of an electronic device;

FIG. 7 is a schematic cross-sectional view illustrating a fan-out semiconductor package;

FIG. 8 is a schematic cross-sectional view illustrating a case in which a fan-out semiconductor package is mounted on a mainboard of an electronic device;

FIG. 9 is a schematic cross-sectional view illustrating an example of a fan-out semiconductor package;

FIG. 10 is a schematic cross-sectional view illustrating another example of a fan-out semiconductor package;

FIG. 11 is a schematic cross-sectional view illustrating another example of a fan-out semiconductor package;

FIG. 12 is a schematic cross-sectional view illustrating another example of a fan-out semiconductor package;

FIG. 13 is a schematic cross-sectional view illustrating another example of a fan-out semiconductor package; and

FIG. 14 is a schematic cross-sectional view illustrating another example of a fan-out semiconductor package.

### DETAILED DESCRIPTION

Hereinafter, exemplary embodiments in the present disclosure will be described with reference to the accompanying drawings. In the accompanying drawings, shapes, sizes, and the like, of components may be exaggerated or shortened for clarity.

Herein, a lower side, a lower portion, a lower surface, and the like, are used to refer to a direction toward a mounting surface of the fan-out semiconductor package in relation to cross sections of the drawings, while an upper side, an upper portion, an upper surface, and the like, are used to refer to an opposite direction to the direction. However, these directions are defined for convenience of explanation, and the claims are not particularly limited by the directions defined as described above.

The meaning of a “connection” of a component to another component in the description includes an indirect connection through an adhesive layer as well as a direct connection between two components. In addition, “electrically connected” conceptually includes a physical connection and a physical disconnection. It can be understood that when an element is referred to with terms such as “first” and “second”, the element is not limited thereby. They may be used only for a purpose of distinguishing the element from the other elements, and may not limit the sequence or importance of the elements. In some cases, a first element may be referred to as a second element without departing from the scope of the claims set forth herein. Similarly, a second element may also be referred to as a first element.

The term “an exemplary embodiment” used herein does not refer to the same exemplary embodiment, and is provided to emphasize a particular feature or characteristic different from that of another exemplary embodiment. However, exemplary embodiments provided herein are considered to be able to be implemented by being combined in whole or in part one with one another. For example, one element described in a particular exemplary embodiment, even if it is not described in another exemplary embodiment, may be understood as a description related to another exemplary embodiment, unless an opposite or contradictory description is provided therein.

Terms used herein are used only in order to describe an exemplary embodiment rather than limiting the present disclosure. In this case, singular forms include plural forms unless interpreted otherwise in context.

Electronic Device

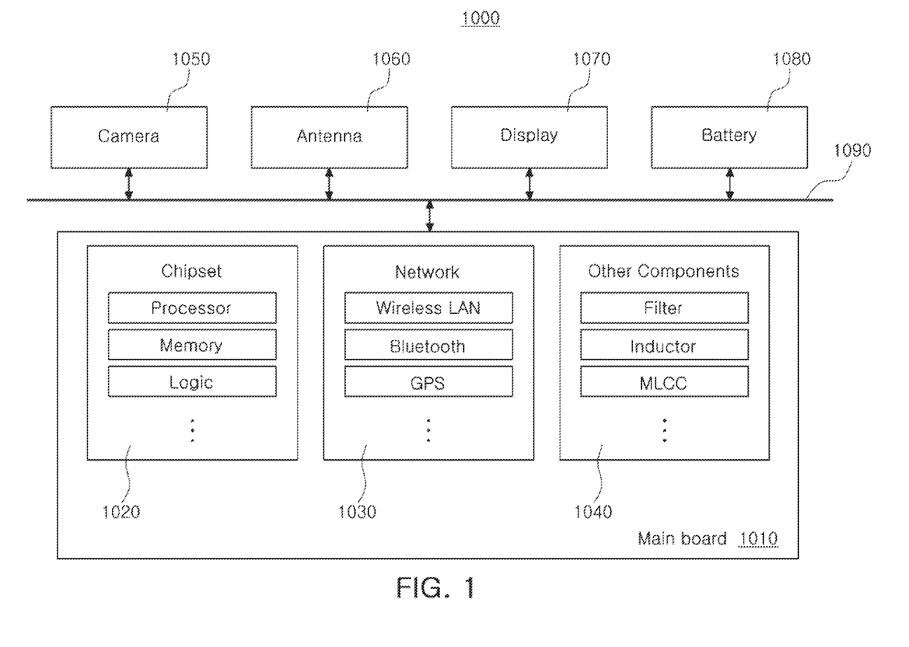

FIG. 1 is a schematic block diagram illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, but may also include other types of chip related components. In addition, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. In addition, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. In addition, other components 1040 may be combined with each other, together with the chip related components 1020 or the network related components 1030 described above.

Depending on a type of the electronic device 1000, the electronic device 1000 may include other components that may or may not be physically or electrically connected to the mainboard 1010. These other components may include, for example, a camera module 1050, an antenna 1060, a display device 1070, a battery 1080, an audio codec (not illustrated), a video codec (not illustrated), a power amplifier (not illustrated), a compass (not illustrated), an accelerometer (not illustrated), a gyroscope (not illustrated), a speaker (not illustrated), a mass storage unit (for example, a hard disk drive) (not illustrated), a compact disk (CD) drive (not illustrated), a digital versatile disk (DVD) drive (not illustrated), or the like. However, these other components are not limited thereto, but may also include other components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

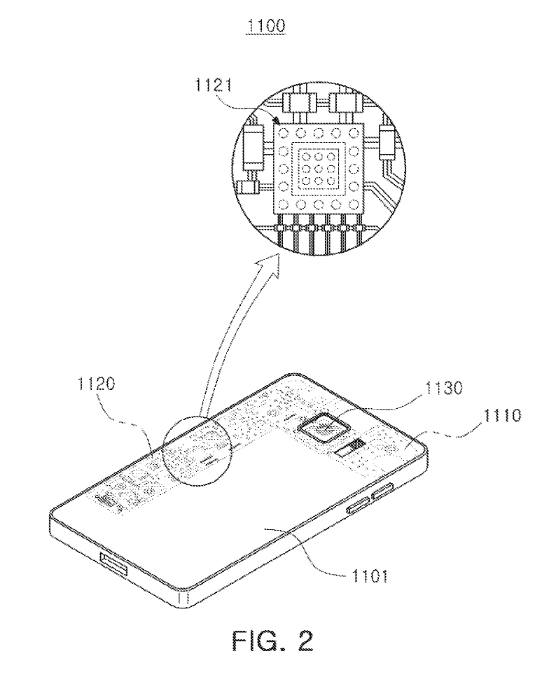

FIG. 2 is a schematic perspective view illustrating an example of an electronic device.

Referring to FIG. 2, a semiconductor package may be used for various purposes in the various electronic devices 1000 as described above. For example, a motherboard 1110 may be accommodated in a body 1101 of a smartphone 1100, and various electronic components 1120 may be physically or electrically connected to the motherboard 1110. In addition, other components that may or may not be physically or electrically connected to the motherboard 1110, such as a camera module 1130, may be accommodated in the body 1101. Some of the electronic components 1120 may be the chip related components, for example, a semiconductor package 1121, but are not limited thereto. The electronic device is not necessarily limited to the smartphone 1100, but may be other electronic devices as described above.

Semiconductor Package

Generally, numerous fine electrical circuits are integrated in a semiconductor chip. However, the semiconductor chip may not serve as a finished semiconductor product in itself, and may be damaged due to external physical or chemical impacts. Therefore, the semiconductor chip itself may not be used, but may be packaged and used in an electronic device, or the like, in a packaged state.

Here, semiconductor packaging is required due to the existence of a difference in a circuit width between the semiconductor chip and a mainboard of the electronic device in terms of electrical connections. In detail, a size of connection pads of the semiconductor chip and an interval between the connection pads of the semiconductor chip are very fine, but a size of component mounting pads of the mainboard used in the electronic device and an interval between the component mounting pads of the mainboard are significantly larger than those of the semiconductor chip. Therefore, it may be difficult to directly mount the semiconductor chip on the mainboard, and packaging technology for buffering a difference in a circuit width between the semiconductor chip and the mainboard is required.

A semiconductor package manufactured by the packaging technology may be classified as a fan-in semiconductor package or a fan-out semiconductor package depending on a structure and a purpose thereof.

The fan-in semiconductor package and the fan-out semiconductor package will hereinafter be described in more detail with reference to the drawings.

Fan-in Semiconductor Package

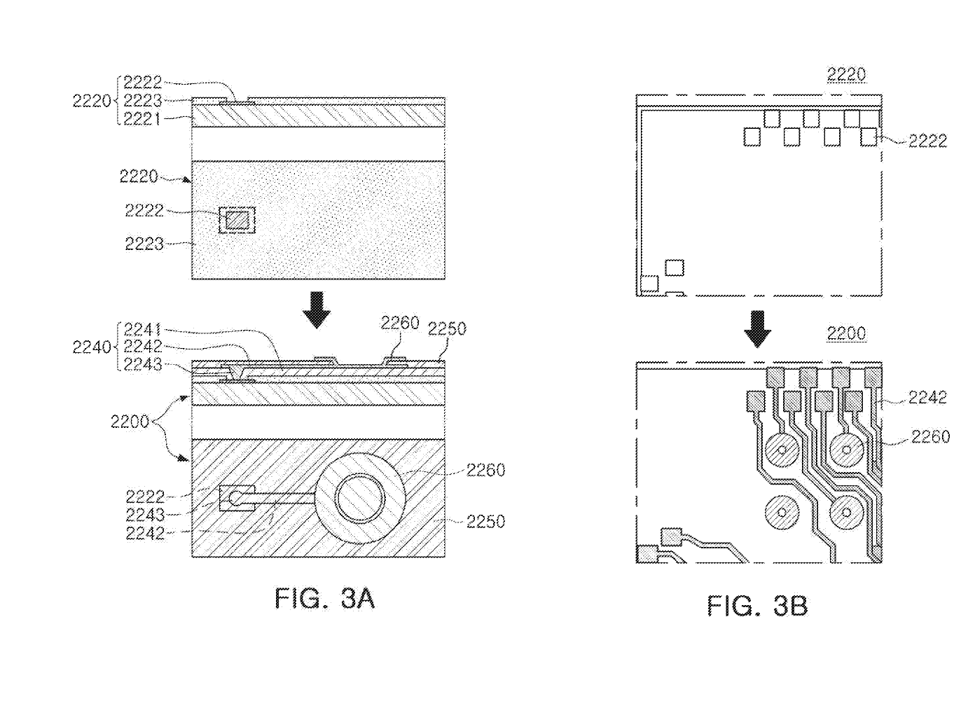

FIGS. 3A and 3B are schematic cross-sectional views illustrating states of a fan-in semiconductor package before and after being packaged.

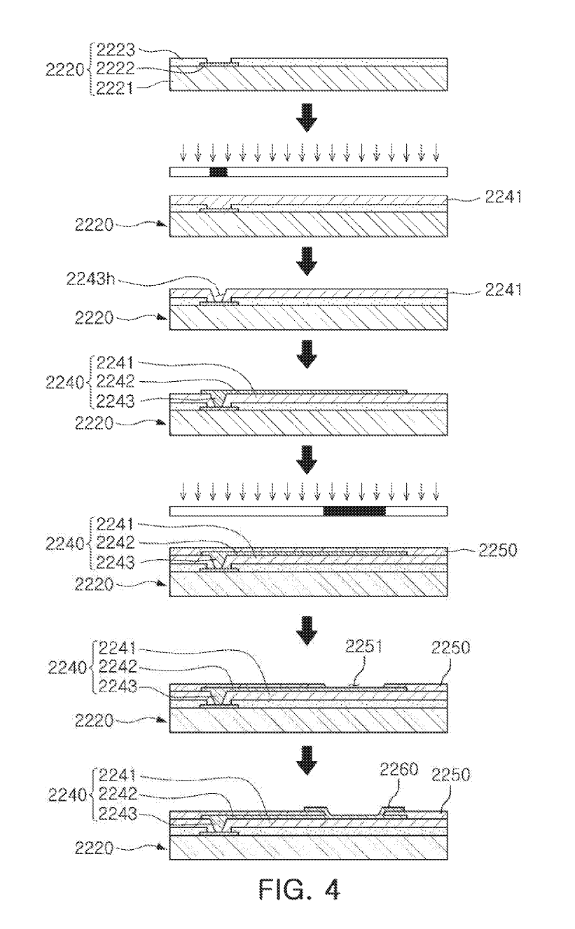

FIG. 4 is schematic cross-sectional views illustrating a packaging process of a fan-in semiconductor package.

Referring to FIGS. 3 and 4, a semiconductor chip 2220 may be, for example, an integrated circuit (IC) in a bare state, including a body 2221 including silicon (Si), germanium (Ge), gallium arsenide (GaAs), or the like, connection pads 2222 formed on one surface of the body 2221 and including a conductive material such as aluminum (Al), or the like, and a passivation layer 2223 such as an oxide film, a nitride film, or the like, formed on one surface of the body 2221 and covering at least portions of the connection pads 2222. In this case, since the connection pads 2222 may be significantly small, it may be difficult to mount the integrated circuit (IC) on an intermediate level printed circuit board (PCB) as well as on the mainboard of the electronic device, or the like.

Therefore, a connection member 2240 may be formed depending on a size of the semiconductor chip 2220 on the semiconductor chip 2220 in order to redistribute the connection pads 2222. The connection member 2240 may be formed by forming an insulating layer 2241 on the semiconductor chip 2220 using an insulating material such as a photoimagable dielectric (PID) resin, forming via holes 2243h opening the connection pads 2222, and then forming wiring patterns 2242 and vias 2243. Then, a passivation layer 2250 protecting the connection member 2240 may be formed, an opening 2251 may be formed, and an underbump metal layer 2260, or the like, may be formed. That is, a fan-in semiconductor package 2200 including, for example, the semiconductor chip 2220, the connection member 2240, the passivation layer 2250, and the underbump metal layer 2260 may be manufactured through a series of processes.

As described above, the fan-in semiconductor package may have a package form in which all of the connection pads, for example, input/output (I/O) terminals, of the semiconductor chip are disposed inside the semiconductor chip, and may have excellent electrical characteristics and be produced at a low cost. Therefore, many elements mounted in smartphones have been manufactured in a fan-in semiconductor package form. In detail, many elements mounted in smartphones have been developed to implement a rapid signal transfer while having a compact size.

However, since all I/O terminals need to be disposed inside the semiconductor chip in the fan-in semiconductor package, the fan-in semiconductor package has significant spatial limitations. Therefore, it is difficult to apply this structure to a semiconductor chip having a large number of I/O terminals or a semiconductor chip having a compact size. In addition, due to the disadvantage described above, the fan-in semiconductor package may not be directly mounted and used on the mainboard of the electronic device. The reason is that even in a case in which a size of the I/O terminals of the semiconductor chip and an interval between the I/O terminals of the semiconductor chip are increased by a redistribution process, the size of the I/O terminals of the semiconductor chip and the interval between the I/O terminals of the semiconductor chip may not be sufficient to directly mount the fan-in semiconductor package on the mainboard of the electronic device.

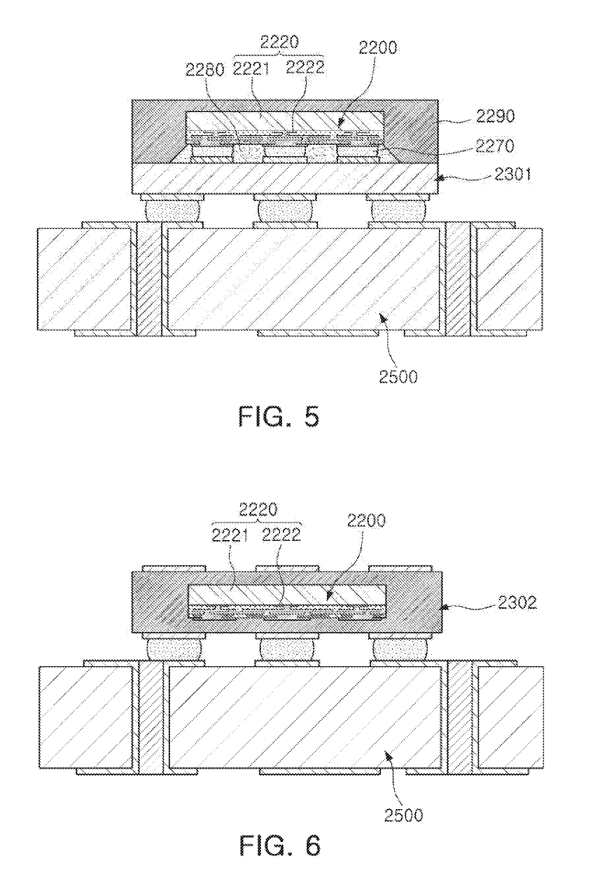

FIG. 5 is a schematic cross-sectional view illustrating a case in which a fan-in semiconductor package is mounted on a ball grid array (BGA) substrate and is ultimately mounted on a mainboard of an electronic device.

FIG. 6 is a schematic cross-sectional view illustrating a case in which a fan-in semiconductor package is embedded in a BGA substrate and is ultimately mounted on a mainboard of an electronic device.

Referring to FIGS. 5 and 6, in a fan-in semiconductor package 2200, connection pads 2222, that is, I/O terminals, of a semiconductor chip 2220 may be redistributed through a BGA substrate 2301, and the fan-in semiconductor package 2200 may be ultimately mounted on a mainboard 2500 of an electronic device in a state in which it is mounted on the BGA substrate 2301. In this case, solder balls 2270, and the like, may be fixed by an underfill resin 2280, or the like, and an outer side of the semiconductor chip 2220 may be covered with a molding material 2290, or the like. Alternatively, a fan-in semiconductor package 2200 may be embedded in a separate BGA substrate 2302, connection pads 2222, that is, I/O terminals, of the semiconductor chip 2220 may be redistributed by the BGA substrate 2302 in a state in which the fan-in semiconductor package 2200 is embedded in the BGA substrate 2302, and the fan-in semiconductor package 2200 may be ultimately mounted on a mainboard 2500 of an electronic device.

As described above, it may be difficult to directly mount and use the fan-in semiconductor package on the mainboard of the electronic device. Therefore, the fan-in semiconductor package may be mounted on the separate BGA substrate and be then mounted on the mainboard of the electronic device through a packaging process or may be mounted and used on the mainboard of the electronic device in a state in which it is embedded in the BGA substrate.

Fan-Out Semiconductor Package

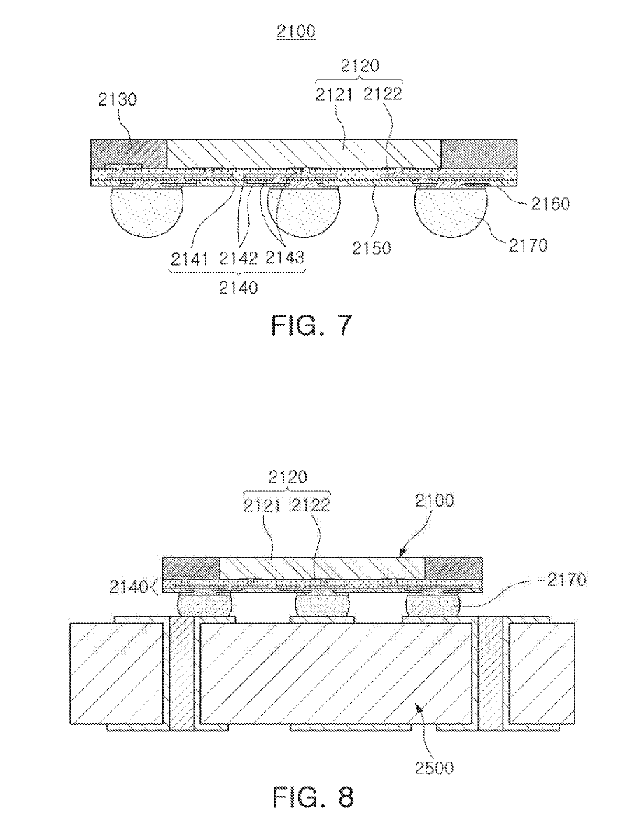

FIG. 7 is a schematic cross-sectional view illustrating a fan-out semiconductor package.

Referring to FIG. 7, in a fan-out semiconductor package 2100, for example, an outer side of a semiconductor chip 2120 may be protected by an encapsulant 2130, and connection pads 2122 of the semiconductor chip 2120 may be redistributed outwardly of the semiconductor chip 2120 by a connection member 2140. In this case, a passivation layer 2150 may further be formed on the connection member 2140, and an underbump metal layer 2160 may further be formed in openings of the passivation layer 2150. Solder balls 2170 may further be formed on the underbump metal layer 2160. The semiconductor chip 2120 may be an integrated circuit (IC) including a body 2121, the connection pads 2122, a passivation layer (not illustrated), and the like. The connection member 2140 may include an insulating layer 2141, redistribution layers 2142 formed on the insulating layer 2141, and vias 2143 electrically connecting the connection pads 2122 and the redistribution layers 2142 to each other.

As described above, the fan-out semiconductor package may have a form in which I/O terminals of the semiconductor chip are redistributed and disposed outwardly of the semiconductor chip through the connection member formed on the semiconductor chip. As described above, in the fan-in semiconductor package, all I/O terminals of the semiconductor chip need to be disposed inside the semiconductor chip. Therefore, when a size of the semiconductor chip is decreased, a size and a pitch of balls need to be decreased, such that a standardized ball layout may not be used in the fan-in semiconductor package. On the other hand, the fan-out semiconductor package has the form in which the I/O terminals of the semiconductor chip are redistributed and disposed outwardly of the semiconductor chip through the connection member formed on the semiconductor chip as described above. Therefore, even in a case in which a size of the semiconductor chip is decreased, a standardized ball layout may be used in the fan-out semiconductor package as it is, such that the fan-out semiconductor package may be mounted on the mainboard of the electronic device without using a separate BGA substrate, as described below.

FIG. 8 is a schematic cross-sectional view illustrating a case in which a fan-out semiconductor package is mounted on a mainboard of an electronic device.

Referring to FIG. 8, a fan-out semiconductor package 2100 may be mounted on a mainboard 2500 of an electronic device through solder balls 2170, or the like. That is, as described above, the fan-out semiconductor package 2100 includes the connection member 2140 formed on the semiconductor chip 2120 and capable of redistributing the connection pads 2122 to a fan-out region that is outside of a size of the semiconductor chip 2120, such that the standardized ball layout may be used in the fan-out semiconductor package 2100 as it is. As a result, the fan-out semiconductor package 2100 may be mounted on the mainboard 2500 of the electronic device without using a separate BGA substrate, or the like.

As described above, since the fan-out semiconductor package may be mounted on the mainboard of the electronic device without using the separate BGA substrate, the fan-out semiconductor package may be implemented at a thickness lower than that of the fan-in semiconductor package using the BGA substrate. Therefore, the fan-out semiconductor package may be miniaturized and thinned. In addition, the fan-out semiconductor package has excellent thermal characteristics and electrical characteristics, such that it is particularly appropriate for a mobile product. Therefore, the fan-out semiconductor package may be implemented in a form more compact than that of a general package-on-package (POP) type using a printed circuit board (PCB), and may solve a problem due to the occurrence of a warpage phenomenon.

Meanwhile, the fan-out semiconductor package refers to package technology for mounting the semiconductor chip on the mainboard of the electronic device, or the like, as described above, and protecting the semiconductor chip from external impacts, and is a concept different from that of a printed circuit board (PCB) such as a BGA substrate, or the like, having a scale, a purpose, and the like, different from those of the fan-out semiconductor package, and having the fan-in semiconductor package embedded therein.

A package-on-package type or package-on-chip type fan-out semiconductor package capable of being thinned and miniaturized in spite of using a plurality of semiconductor chips, reducing signal loss by shortening a connection distance between chips, and having improved reliability by securing sufficient rigidity will hereinafter be described with reference to the drawings.

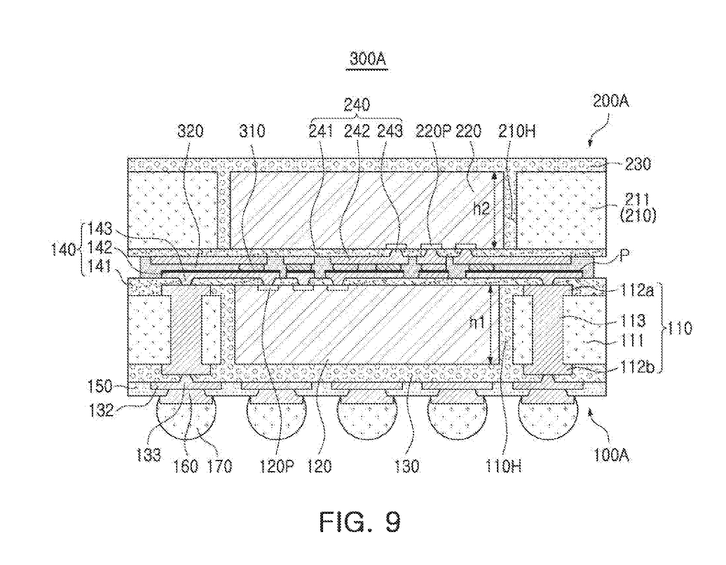

FIG. 9 is a schematic cross-sectional view illustrating an example of a fan-out semiconductor package.

Referring to FIG. 9, a fan-out semiconductor package 300A according to an exemplary embodiment in the present disclosure may include a first structure 100A including a first core member 110 having a first through-hole 110H, a first semiconductor chip 120 disposed in the first through-hole 110H and having a first active surface having first connection pads 120P disposed thereon and a first inactive surface opposing the first active surface, a first encapsulant 130 encapsulating at least portions of the first semiconductor chip 120 and filling at least portions of the first through-hole 110H, and a first connection member 140 disposed on the first core member 110 and the first active surface and including a first redistribution layer 142 electrically connected to the first connection pads 120P; and a second structure 200A including a second core member 210 having a second through-hole 210H, a second semiconductor chip 220 disposed in the second through-hole 210H and having a second active surface having second connection pads 220P disposed thereon and a second inactive surface opposing the second active surface, a second encapsulant 230 encapsulating at least portions of the second semiconductor chip 220 and filling at least portions of the second through-hole 210H, and a second connection member 240 disposed on the second core member 210 and the second active surface and including a second redistribution layer 242 electrically connected to the second connection pads 220P. The first structure 100A and the second structure 200A may be disposed so that the first and second active surfaces face each other, and the first and second redistribution layers 142 and 242 may be connected to each other through low melting point metals 310. An underfill resin 320 may be disposed between the first and second connection members 140 and 240, and may cover the first and second redistribution layers 142 and 242 and the low melting point metals 310. The underfill resin 320 may not cover edges portions of a first insulating layer 141 of the first connection member 140 on which the first redistribution layer 142 is disposed, and the underfill resin 320 may not cover edges portions of a second insulating layer 241 of the second connection member 240 on which the second redistribution layer 242 is disposed. The first core member 110 includes a plurality of wiring layers 112a and 112b and vias 113, and may thus serve as a connection member connecting upper and lower portions to each other, and the wiring layers 112a and 112b may be electrically connected to the first connection pads 120P through the first redistribution layer 142. In addition, the wiring layers 112a and 112b may also be electrically connected to the second connection pads 220P through the second redistribution layer 242.

The first structure 100A may further include a backside wiring layer 132 disposed on the other surface of the first encapsulant 130 opposing one surface of the first encapsulant 130 on which the first connection member 140 is disposed, backside vias 133 penetrating through at least portions of the first encapsulant 130 and connecting the backside wiring layer 132 to a second wiring layer 112b of the first core member 110, a passivation layer 150 disposed on the first encapsulant 130 and having openings exposing at least portions of the backside wiring layer 132, underbump metal layers 160 formed in the openings of the passivation layer 150 and connected to the exposed backside wiring layer 132, and electrical connection structures 170 disposed on the passivation layer 150 and connected to the underbump metal layers 160, if necessary. In this way, the fan-out semiconductor package 300A according to the exemplary embodiment may be mounted on and be electrically connected to the mainboard of the electronic device.

In the fan-out semiconductor package 300A according to the exemplary embodiment, the first and second semiconductor chips 120 and 220 may be disposed in a package-on-package form, and the first semiconductor chip 120 and the second semiconductor chip 220 may be disposed so that the first and second active surfaces face each other. In addition, the first and second redistribution layers 142 and 242 redistributing the first and second connection pads 120P and 220P of the first and second semiconductor chips 120 and 220, respectively, may also be disposed to face each other. In this case, the first and second redistribution layers 142 and 242 may be directly connected to each other by the low melting point metals 310, and may be protected at a time by the underfill resin 320, or the like. That is, even though the fan-out semiconductor package 300A has a package-on-package form, the fan-out semiconductor package 300A may be thinned as much as possible, and a signal path between the first and second semiconductor chips 120 and 220 may be significantly reduced. The fan-out semiconductor package 300A has the package-on-package form, and may thus be basically miniaturized. In addition, such a connection form may implement a package-on-package without using a separate expensive material such as a photoimagable encapsulant (PIE), or the like, and may also be reworked to reduce a cost. Particularly, when the first and second semiconductor chips 120 and 220 are memory chips, the fan-out semiconductor package 300A has large advantages in terms of thinness, miniaturization, signal stability, a cost, and the like, as compared to a stack package using wire bonding according to the related art.

The respective components included in the fan-out semiconductor package 300A according to the exemplary embodiment will hereinafter be described in more detail.

First, the first structure 100A may include the first core member 110 having the first through-hole 110H, the first semiconductor chip 120 disposed in the first through-hole 110H and having the first active surface having the first connection pads 120P disposed thereon and the first inactive surface opposing the first active surface, the first encapsulant 130 encapsulating at least portions of the first semiconductor chip 120 and filling at least portions of the first through-hole 110H, and the first connection member 140 disposed on the first core member 110 and the first active surface and including the first redistribution layer 142 electrically connected to the first connection pads 120P. In addition, the first structure 100A may further include the backside wiring layer 132 disposed on the other surface of the first encapsulant 130 opposing one surface of the first encapsulant 130 on which the first connection member 140 is disposed, the backside vias 133 penetrating through at least portions of the first encapsulant 130 and connecting the backside wiring layer 132 to the second wiring layer 112b of the first core member 110, the passivation layer 150 disposed on the first encapsulant 130 and having the openings exposing at least portions of the backside wiring layer 132, the underbump metal layers 160 formed in the openings of the passivation layer 150 and connected to the exposed backside wiring layer 132, and the electrical connection structures 170 disposed on the passivation layer 150 and connected to the underbump metal layers 160, if necessary.

The first core member 110 may maintain rigidity of the first structure 100A depending on certain materials, and serve to secure uniformity of a thickness of the first encapsulant 130. The first connection pads 120P of the first semiconductor chip 120 may be electrically connected to the mainboard of the electronic device through the electrical connection structures 170, or the like, by the first core member 110. The first core member 110 may include the plurality of wiring layers 112a and 112b to effectively redistribute the first connection pads 120P of the first semiconductor chip 120, and may provide a wide wiring design region to suppress redistribution layers from being formed in other regions. The first semiconductor chip 120 may be disposed in the first through-hole 110H to be spaced apart from the first core member 110 by a predetermined distance. Side surfaces of the first semiconductor chip 120 may be surrounded by the first core member 110. The first core member 110 may include an insulating layer 111, a first wiring layer 112a disposed on an upper surface of the insulating layer 111, the second wiring layer 112b disposed on a lower surface of the insulating layer 111, and the vias 113 penetrating through the insulating layer 111 and electrically connecting the first and second wiring layers 112a and 112b to each other.

For example, a material including an inorganic filler and an insulating resin may be used as a material of the insulating layer 111. For example, a thermosetting resin such as an epoxy resin, a thermoplastic resin such as a polyimide resin, or a resin including a reinforcing material such as an inorganic filler, for example, silica, alumina, or the like, more specifically, Ajinomoto Build up Film (ABF), FR-4, Bismaleimide Triazine (BT), a photoimagable dielectric (PID) resin, or the like, may be used. Alternatively, a material in which a thermosetting resin or a thermoplastic resin is impregnated together with an inorganic filler in a core material such as a glass fiber (or a glass cloth or a glass fabric), for example, prepreg, or the like, may also be used. In this case, excellent rigidity of the first structure 100A may be maintained, such that the first core member 110 may be used as a kind of support member.

The wiring layers 112a and 112b may include a conductive material such as copper (Cu), aluminum (Al), silver (Ag), tin (Sn), gold (Au), nickel (Ni), lead (Pb), titanium (Ti), or alloys thereof. The wiring layers 112a and 112b may perform various functions depending on designs of corresponding layers. For example, the wiring layers 112a and 112b may include ground (GND) patterns, power (PWR) patterns, signal (S) patterns, and the like. Here, the signal (S) patterns may include various signals except for the ground (GND) patterns, the power (PWR) patterns, and the like, such as data signals, and the like. In addition, the wiring layers 112a and 112b may include pad patterns for vias, pad patterns for electrical connection structures, and the like. Thicknesses of the wiring layers 112a and 112b of the first core member 110 may be greater than that of the first redistribution layer 142 of the first connection member 140. The reason is that the first core member 110 may have a thickness similar to that of the first semiconductor chip 120, but the first connection member 140 needs to be thinned.

The vias 113 may penetrate through the insulating layer 111 and electrically connect the first wiring layer 112a and the second wiring layer 112b to each other. A material of each of the vias 113 may be a conductive material. Each of the vias 113 may be completely filled with the conductive material, or the conductive material may be formed along a wall of each of via holes. Each of the vias 113 may be a through-via completely penetrating through the insulating layer 111, and may have a cylindrical shape or a hourglass shape, but is not limited thereto.

The first semiconductor chip 120 may be an integrated circuit (IC) provided in an amount of several hundred to several million or more elements integrated in a single chip. The first semiconductor chip 120 may be formed on the basis of an active wafer. In this case, a base material of a body may be silicon (Si), germanium (Ge), gallium arsenide (GaAs), or the like. Various circuits may be formed on the body. The first connection pads 120P may electrically connect the first semiconductor chip 120 to other components, and a conductive material such as aluminum (Al), or the like, may be used as a material of each of the first connection pads 120P. An active surface of the first semiconductor chip 120 refers to a surface of the first semiconductor chip 120 on which the first connection pads 120P are disposed, and an inactive surface of the first semiconductor chip 120 refers to a surface of the first semiconductor chip 120 opposing the active surface. A passivation layer (not illustrated) covering at least portions of the first connection pads 120P may be formed on the body, if necessary. The passivation layer (not illustrated) may be an oxide film, a nitride film, or the like, or be a double layer of an oxide layer and a nitride layer. An insulating layer (not illustrated), and the like, may also be further disposed in other required positions. The first semiconductor chip 120 may be a memory chip such as a volatile memory (such as a DRAM), a non-volatile memory (such as a ROM), a flash memory, or the like. However, the first semiconductor chip 120 is not limited thereto, but may also be another kind of chip.

The first encapsulant 130 may protect the first semiconductor chip 120. An encapsulation form of the first encapsulant 130 is not particularly limited, but may be a form in which the first encapsulant 130 surrounds at least portions of the first semiconductor chip 120. In this case, the first encapsulant 130 may cover the first core member 110 and the inactive surface of the first semiconductor chip 120, and fill at least portions of the first through-hole 110H. A certain material of the first encapsulant 130 is not particularly limited, but may be, for example, an insulating material. For example, the first encapsulant 130 may include ABF including an insulating resin and an inorganic filler. However, the material of the second encapsulant 230 is not limited thereto, but may also be a PIE.

The first connection member 140 may include the first redistribution layer 142 that may redistribute the first connection pads 120P of the first semiconductor chip 120. Several tens to several millions of first connection pads 120P having various functions may be redistributed by the first connection member 140, and may be physically or electrically externally connected through the electrical connection structures 170 depending on the functions. The first connection member 140 may include the first insulating layer 141, the first redistribution layer 142 disposed on the first insulating layer 141, and first vias 143 electrically connecting the first redistribution layer 142 to the first wiring layer 112a and the first connection pads 120P. The first connection member 140 may include larger numbers of insulating layers, redistribution layers, and vias, if necessary.

A material of the first insulating layer 141 may be an insulating material. In this case, a photosensitive insulating material such as a PID resin may also be used as the insulating material. This case may be advantageous in forming fine patterns.

The first redistribution layer 142 may include a conductive material such as copper (Cu), aluminum (Al), silver (Ag), tin (Sn), gold (Au), nickel (Ni), lead (Pb), titanium (Ti), or alloys thereof. The first redistribution layer 142 may perform various functions depending on a design of a corresponding layer. For example, the first redistribution layer 142 may include ground (GND) patterns, power (PWR) patterns, signal (S) patterns, and the like. Here, the signal (S) patterns may include various signals except for the ground (GND) patterns, the power (PWR) patterns, and the like, such as data signals, and the like. In addition, the first redistribution layer 142 may include pad patterns for vias, pad patterns for electrical connection structures, and the like.

The first vias 143 may electrically connect the first connection pads 120P, the first redistribution layer 142, the first wiring layer 112a, and the like, formed on different layers to each other, resulting in an electrical path in the first structure 100A. A material of each of the first vias 143 may be a conductive material such as copper (Cu), aluminum (Al), silver (Ag), tin (Sn), gold (Au), nickel (Ni), lead (Pb), titanium (Ti), or alloys thereof. Each of the first vias 143 may be completely filled with the conductive material, or the conductive material may also be formed along a wall of each of vias. In addition, each of the vias 143 may have any shape known in the related art such as a tapered shape. The first vias 143 may be in physical contact with the first connection pads 120P of the first semiconductor chip 120. That is, the first semiconductor chip 120 may be in a bare die form, and the first connection member 140 may be a redistribution layer (RDL) directly formed on the first active surface.

The backside wiring layer 132 may provide a routing region on the other surface of the first encapsulant 130 opposing one surface of the first encapsulant 130 on which the first connection member 140 is disposed. The backside wiring layer 132 may include a conductive material such as copper (Cu), aluminum (Al), silver (Ag), tin (Sn), gold (Au), nickel (Ni), lead (Pb), titanium (Ti), or alloys thereof. The backside wiring layer 132 may perform various functions depending on a design of a corresponding layer. For example, the backside wiring layer 132 may include ground (GND) patterns, power (PWR) patterns, signal (S) patterns, and the like. Here, the signal (S) patterns may include various signals except for the ground (GND) patterns, the power (PWR) patterns, and the like, such as data signals, and the like. In addition, the backside wiring layer 132 may include pad patterns for vias, pad patterns for electrical connection structures, and the like.

The backside vias 133 may electrically connect the backside wiring layer 132 to the second wiring layer 112b of the first core member 110. A material of each of the backside vias 133 may be a conductive material such as copper (Cu), aluminum (Al), silver (Ag), tin (Sn), gold (Au), nickel (Ni), lead (Pb), titanium (Ti), or alloys thereof. Each of the backside vias 133 may be completely filled with a conductive material, or the conductive material may be formed along a wall of each of the vias. In addition, each of the backside vias 133 may have any shape known in the related art such as a tapered shape.

The passivation layer 150 may protect the backside wiring layer 132. The passivation layer 150 may include an insulating material such as ABF. However, the passivation layer 150 is not limited thereto, but may also include a general solder resist, or the like. The passivation layer 150 may have the openings exposing at least portions of the backside wiring layer 132. The number of openings may be several tens or several millions depending on a design.

The underbump metal layers 160 may be additionally configured to improve connection reliability of the electrical connection structures 170 to improve board level reliability of the fan-out semiconductor package 300A. The underbump metal layers 160 may be connected to the backside wiring layer 132 exposed through the openings of the passivation layer 150. In this case, a surface treatment layer (not illustrated) may be formed on the exposed backside wiring layer 132, if necessary. The surface treatment layer may include Ni—Au. The underbump metal layers 160 may be formed by any known metallization method using any known conductive material such as a metal, but are not limited thereto.

The electrical connection structures 170 may be additionally configured to physically or electrically externally connect the fan-out semiconductor package 300A. For example, the fan-out semiconductor package 300A may be mounted on the mainboard of the electronic device, or the like, through the electrical connection structures 170. Each of the electrical connection structures 170 may be formed of a low melting point metal, for example, a solder such as an alloy including tin (Sn), more specifically, a tin (Sn)-aluminum (Al)-copper (Cu) alloy, or the like. However, this is only an example, and a material of each of the electrical connection structures 170 is not particularly limited thereto. Each of the electrical connection structures 170 may be a land, a ball, a pin, or the like. The electrical connection structures 170 may be formed as a multilayer or single layer structure. When the electrical connection structures 170 are formed as a multilayer structure, the electrical connection structures 170 may include a copper (Cu) pillar and a solder. When the electrical connection structures 170 are formed as a single layer structure, the electrical connection structures 170 may include a tin-silver solder or copper (Cu). However, this is only an example, and the electrical connection structures 170 are not limited thereto.

The number, an interval, a disposition form, and the like, of electrical connection structures 170 are not particularly limited, but may be sufficiently modified depending on design particulars by those skilled in the art. For example, the electrical connection structures 170 may be provided in an amount of several tens to several millions according to the numbers of first and second connection pads 120P and 220P of the first and second semiconductor chips 120 and 220, or may be provided in an amount of several tens to several millions or more or several tens to several millions or less.

At least one of the electrical connection structures 170 may be disposed in a fan-out region. The fan-out region refers to a region except for a region in which the first semiconductor chip 120 is disposed in, for example, the first structure 100A. That is, the fan-out semiconductor package 300A according to the exemplary embodiment may be a fan-out package. The fan-out package may have excellent reliability as compared to a fan-in package, may implement a plurality of input/output (I/O) terminals, and may facilitate a 3D interconnection. In addition, as compared to a ball grid array (BGA) package, a land grid array (LGA) package, or the like, the fan-out package may be mounted on an electronic device without a separate board. Thus, the fan-out package may be manufactured to have a small thickness, and may have price competitiveness.

Next, the second structure 200A may include the second core member 210 having the second through-hole 210H, the second semiconductor chip 220 disposed in the second through-hole 210H and having the second active surface having the second connection pads 220P disposed thereon and the second inactive surface opposing the second active surface, the second encapsulant 230 encapsulating at least portions of the second semiconductor chip 220 and filling at least portions of the second through-hole 210H, and the second connection member 240 disposed on the second core member 210 and the second active surface and including the second redistribution layer 242 electrically connected to the second connection pads 220.

The second core member 210 may maintain rigidity of the second structure 200A depending on certain materials, and serve to secure uniformity of a thickness of the second encapsulant 230. The second semiconductor chip 220 may be disposed in the second through-hole 210H to be spaced apart from the second core member 210 by a predetermined distance. Side surfaces of the second semiconductor chip 220 may be surrounded by the second core member 210. The second core member 210 may include an insulating layer 211.

For example, a material including an inorganic filler and an insulating resin may be used as a material of the insulating layer 211. For example, a thermosetting resin such as an epoxy resin, a thermoplastic resin such as a polyimide resin, or a resin including a reinforcing material such as an inorganic filler, for example, silica, alumina, or the like, more specifically, ABF, FR-4, BT, a PID resin, or the like, may be used. Alternatively, a material in which a thermosetting resin or a thermoplastic resin is impregnated together with an inorganic filler in a core material such as a glass fiber (or a glass cloth or a glass fabric), for example, prepreg, or the like, may also be used. In this case, excellent rigidity of the second structure 200A may be maintained, such that the second core member 210 may be used as a kind of support member.

The second semiconductor chip 220 may be an integrated circuit (IC) provided in an amount of several hundred to several million or more elements integrated in a single chip. The second semiconductor chip 220 may be formed on the basis of an active wafer. In this case, a base material of a body may be silicon (Si), germanium (Ge), gallium arsenide (GaAs), or the like. Various circuits may be formed on the body. The second connection pads 220P may electrically connect the second semiconductor chip 220 to other components, and a conductive material such as aluminum (Al), or the like, may be used as a material of each of the second connection pads 220P. An active surface of the second semiconductor chip 220 refers to a surface of the second semiconductor chip 220 on which the second connection pads 220P are disposed, and an inactive surface of the second semiconductor chip 220 refers to a surface of the second semiconductor chip 220 opposing the active surface. A passivation layer (not illustrated) covering at least portions of the second connection pads 220P may be formed on the body, if necessary. The passivation layer (not illustrated) may be an oxide film, a nitride film, or the like, or be a double layer of an oxide layer and a nitride layer. An insulating layer (not illustrated), and the like, may also be further disposed in other required positions. The second semiconductor chip 220 may be a memory chip such as a volatile memory (such as a DRAM), a non-volatile memory (such as a ROM), a flash memory, or the like. However, the second semiconductor chip 220 is not limited thereto, but may also be another kind of chip.

The second encapsulant 230 may protect the second semiconductor chip 220. An encapsulation form of the second encapsulant 230 is not particularly limited, but may be a form in which the second encapsulant 230 surrounds at least portions of the second semiconductor chip 220. In this case, the second encapsulant 230 may cover the second core member 210 and the inactive surface of the second semiconductor chip 220, and fill at least portions of the second through-hole 210H. A certain material of the second encapsulant 230 is not particularly limited, but may be, for example, an insulating material. For example, the second encapsulant 230 may include ABF including an insulating resin and an inorganic filler. However, the material of the second encapsulant 230 is not limited thereto, but may also be a PIE.

The second connection member 240 may include the second redistribution layer 242 that may redistribute the second connection pads 220P of the second semiconductor chip 220. Several tens to several millions of second connection pads 220P having various functions may be redistributed by the second connection member 240, and may be physically or electrically externally connected through the electrical connection structures 170 depending on the functions. The second connection member 240 may include the second insulating layer 241, the second redistribution layer 242 disposed on the second insulating layer 241, and second vias 243 electrically connecting the second redistribution layer 242 to the second connection pads 220P. The second connection member 240 may include larger numbers of insulating layers, redistribution layers, and vias, if necessary.

A material of the second insulating layer 241 may be an insulating material. In this case, a photosensitive insulating material such as a PID resin may also be used as the insulating material. This case may be advantageous in forming fine patterns.

The second redistribution layer 242 may include a conductive material such as copper (Cu), aluminum (Al), silver (Ag), tin (Sn), gold (Au), nickel (Ni), lead (Pb), titanium (Ti), or alloys thereof. The second redistribution layer 242 may perform various functions depending on a design of a corresponding layer. For example, the second redistribution layer 242 may include ground (GND) patterns, power (PWR) patterns, signal (S) patterns, and the like. Here, the signal (S) patterns may include various signals except for the ground (GND) patterns, the power (PWR) patterns, and the like, such as data signals, and the like. In addition, the second redistribution layer 242 may include pad patterns for vias, pad patterns for electrical connection structures, and the like.

The second vias 243 may electrically connect the second connection pads 220P, the second redistribution layer 242, and the like, formed on different layers to each other, resulting in an electrical path in the second structure 200A. A material of each of the second vias 243 may be a conductive material such as copper (Cu), aluminum (Al), silver (Ag), tin (Sn), gold (Au), nickel (Ni), lead (Pb), titanium (Ti), or alloys thereof. Each of the second vias 243 may be completely filled with the conductive material, or the conductive material may also be formed along a wall of each of vias. In addition, each of the second vias 243 may have any shape known in the related art such as a tapered shape. The second vias 243 may be in physical contact with the second connection pads 220P of the second semiconductor chip 220. That is, the second semiconductor chip 220 may be in a bare die form, and the second connection member 240 may be a redistribution layer (RDL) directly formed on the second active surface.

The first redistribution layer 142 and the second redistribution layer 242 may be connected to each other through the low melting point metals 310. That is, the first redistribution layer 142 and the second redistribution layer 242 may be in physical contact with the low melting point metals 310. The low melting point metal 310 refers to a metal of which a base material is not melted and only a filler metal is melted and which is used for bonding, such as a solder, and may be, for example, tin (Sn) or an alloy including tin (Sn) such as a tin (Sn)-aluminum (Al) alloy or a tin (Sn)-aluminum (Al)-copper (Cu) alloy, but is not limited thereto. Meanwhile, a melting point of the low melting point metal 310 may be higher than that of the electrical connection structure 170. A surface treatment layer (P) may be formed on a surface of the first redistribution layer 142 in contact with the low melting point metal 310. In this case, the surface treatment layer (P) may include one or more of palladium (Pd), nickel (Ni), and gold (Au).

The underfill resin 320 may be disposed between the first connection member 140 and the second connection member 240, and may cover the first redistribution layer 142, the second redistribution layer 242, and the low melting point metals 310. The underfill resin 320 may include an epoxy resin, or the like.

A thickness h1 of the first semiconductor chip 120 may be greater than a thickness h2 of the second semiconductor chip 220. In this case, a package-on-package form more robust against warpage may be implemented. To the contrary, the thickness h2 of the second semiconductor chip 220 may also be greater than the thickness h1 of the first semiconductor chip 120. In this case, a through-path of the via 113 penetrating through the first core member 110 may be significantly reduced, and a signal path may thus be shortened. The thickness h1 of the first semiconductor chip 120 and the thickness h2 of the second semiconductor chip 220 may also be the same as each other, if necessary.

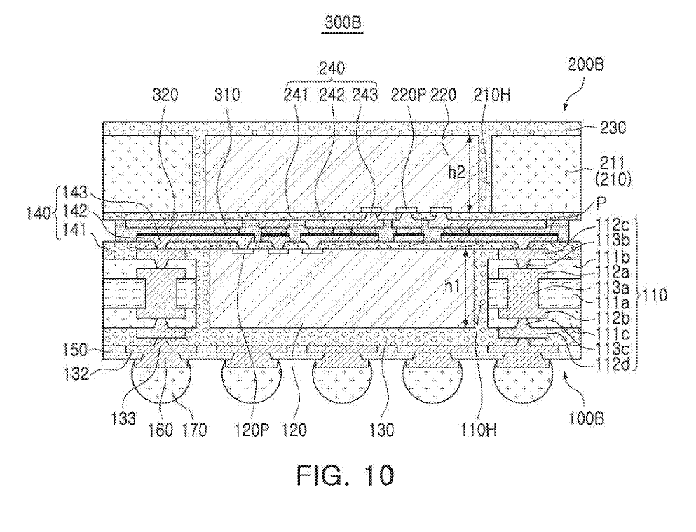

FIG. 10 is a schematic cross-sectional view illustrating another example of a fan-out semiconductor package.

Referring to FIG. 10, in a fan-out semiconductor package 300B according to another exemplary embodiment in the present disclosure, a first structure 100B and a second structure 200B may have a package-on-package form, and a first core member 110 of the first structure 100B may include a larger number of wiring layers 112a, 112b, 112c, and 112d. In more detail, the first core member 110 may include a first insulating layer 111a, a first wiring layer 112a and a second wiring layer 112b disposed on opposite surfaces of the first insulating layer 111a, respectively, a second insulating layer 111b disposed on the first insulating layer 111a and covering the first wiring layer 112a, a third wiring layer 112c disposed on the second insulating layer 111b, a third insulating layer 111c disposed on the first insulating layer 111a and covering the second wiring layer 112b, and a fourth wiring layer 112d disposed on the third insulating layer 111c. The first to fourth wiring layers 112a, 112b, 112c, and 112d may be electrically connected to first connection pads 120P. Since the first core member 110 may include a larger number of wiring layers 112a, 112b, 112c, and 112d, a first connection member 140 may further be simplified. Therefore, a decrease in a yield depending on a defect occurring in a process of forming the first connection member 140 may be suppressed. Meanwhile, the first to fourth wiring layers 112a, 112b, 112c, and 112d may be electrically connected to each other through first to third vias 113a, 113b, and 113c penetrating through the first to third insulating layers 111a, 111b, and 111c, respectively.

The first insulating layer 111a may have a thickness greater than those of the second insulating layer 111b and the third insulating layer 111c. The first insulating layer 111a may be basically relatively thick in order to maintain rigidity, and the second insulating layer 111b and the third insulating layer 111c may be introduced in order to form a larger number of wiring layers 112c and 112d. The first insulating layer 111a may include an insulating material different from those of the second insulating layer 111b and the third insulating layer 111c. For example, the first insulating layer 111a may be, for example, prepreg including a core material, a filler, and an insulating resin, and the second insulating layer 111b and the third insulating layer 111c may be an ABF or a PID film including a filler and an insulating resin. However, the materials of the first insulating layer 111a and the second and third insulating layers 111b and 111c are not limited thereto. Similarly, the first vias 113a penetrating through the first insulating layer 111a may have a diameter greater than those of second vias 113b and third vias 113c penetrating through the second insulating layer 111b and the third insulating layer 111c, respectively.

The first wiring layer 112a and the second wiring layer 112b of the first core member 110 may be disposed on a level between an active surface and an inactive surface of a first semiconductor chip 120. The first core member 110 may be formed at a thickness corresponding to that of the first semiconductor chip 120, and the first wiring layer 112a and the second wiring layer 112b formed in the first core member 110 may thus be disposed on the level between the active surface and the inactive surface of the first semiconductor chip 120. Thicknesses of the wiring layers 112a, 112b, 112c, and 112d of the first core member 110 may be greater than that of the first redistribution layer 142 of the first connection member 140. A description of other configurations overlaps that described above, and is thus omitted.

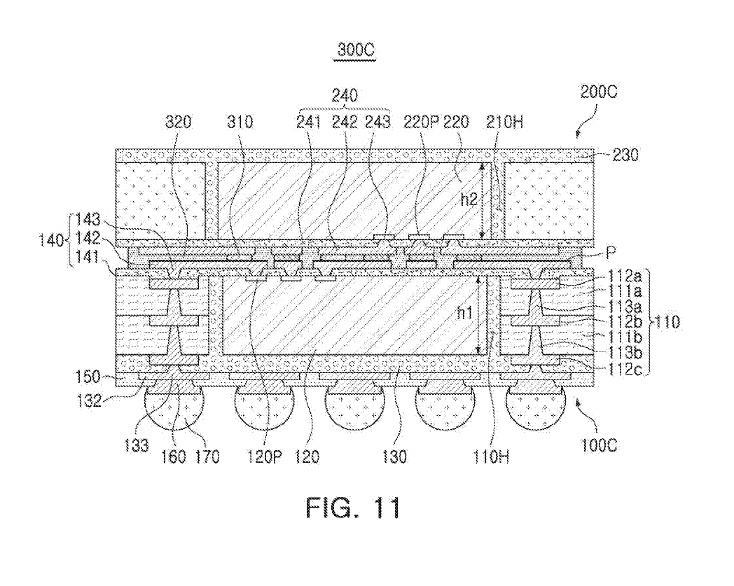

FIG. 11 is a schematic cross-sectional view illustrating another example of a fan-out semiconductor package.

Referring to FIG. 11, in a fan-out semiconductor package 300C according to another exemplary embodiment in the present disclosure, a first structure 100C and a second structure 200C may have a package-on-package form, a first core member 110 of the first structure 100C may include a first insulating layer 111a in contact with a first connection member 140, a first wiring layer 112a in contact with the first connection member 140 and embedded in the first insulating layer 111a, a second wiring layer 112b disposed on the other surface of the first insulating layer 111a opposing one surface of the first insulating layer 111a in which the first wiring layer 112a is embedded, a second insulating layer 111b disposed on the first insulating layer 111a and covering the second wiring layer 112b, and a third wiring layer 112c disposed on the second insulating layer 111b. The first to third wiring layers 112a, 112b, and 112c may be electrically connected to first connection pads 120P. The first and second wiring layers 112a and 112b and the second and third wiring layers 112b and 112c may be electrically connected to each other through first and second vias 113a and 113b penetrating through the first and second insulating layers 111a and 111b, respectively.

An upper surface of the first wiring layer 112a of the first core member 110 may be disposed on a level below an upper surface of the first connection pad 120P of a first semiconductor chip 120. In addition, a distance between a first redistribution layer 142 of the first connection member 140 and the first wiring layer 112a of the first core member 110 may be greater than that between the first redistribution layer 142 of the first connection member 140 and the first connection pad 120P of the first semiconductor chip 120. The reason is that the first wiring layer 112a may be recessed into the first insulating layer 111a. As described above, when the first wiring layer 112a is recessed in the first insulating layer 111a, such that an upper surface of the first insulating layer 111a and the upper surface of the first wiring layer 112a have a step therebetween, a phenomenon in which a material of a first encapsulant 130 bleeds to pollute the first wiring layer 112a may be prevented. The second wiring layer 112b of the first core member 110 may be disposed on a level between an active surface and an inactive surface of the first semiconductor chip 120. Thicknesses of the wiring layers 112a, 112b, and 112c of the first core member 110 may be greater than that of the first redistribution layer 142 of the first connection member 140. A description of other configurations overlaps that described above, and is thus omitted.

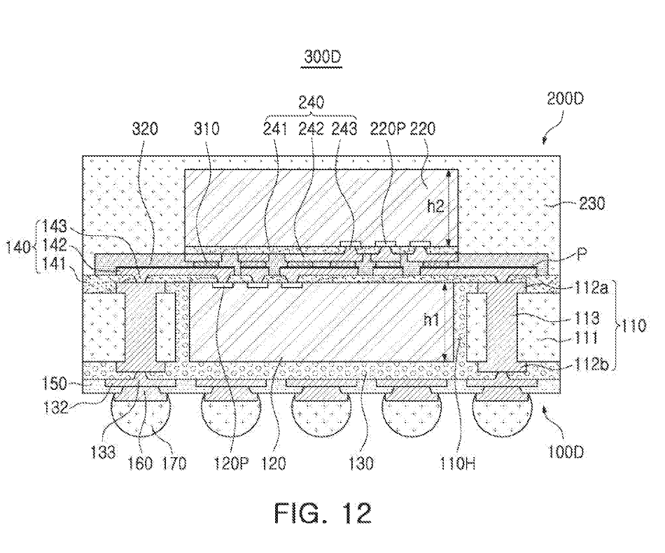

FIG. 12 is a schematic cross-sectional view illustrating another example of a fan-out semiconductor package.

Referring to FIG. 12, in a fan-out semiconductor package 300D according to another exemplary embodiment in the present disclosure, a first structure 100D and a second structure 200D may have a package-on-die form. That is, a second semiconductor chip 220 and a second connection member 240 of the second structure 200D may have a wafer level chip scale package (WCSP) form, and may have a form in which it is surface-mounted on the first structure 100D in the WCSP form as described above and is then encapsulated by a second encapsulant 230. The second encapsulant 230 may be in contact with the first insulating layer 141 of the first connection member 140 on which the first redistribution layer 142 is disposed. In this case, a process of manufacturing the fan-out semiconductor package 300D may further be simplified. A description of other configurations overlaps that described above, and is thus omitted. Meanwhile, a first core member 110 of the first structure 100D may have a form of the first core member 100 of the fan-out semiconductor packages 300B and 300C according to another exemplary embodiment described above.

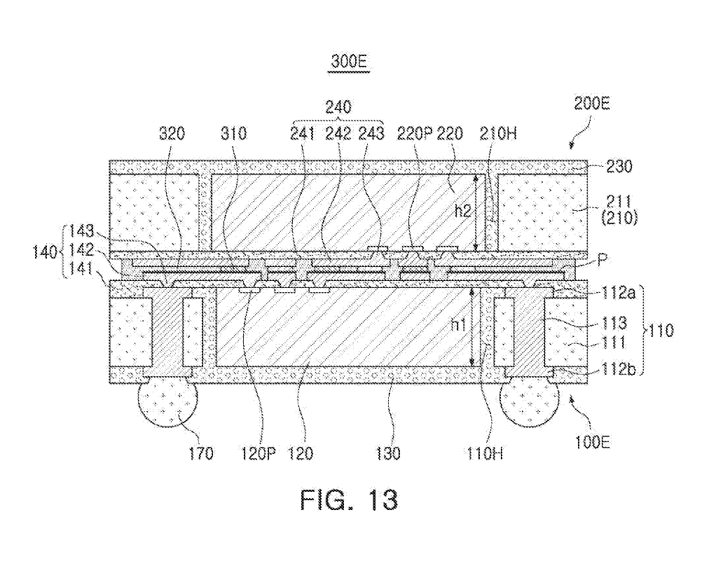

FIG. 13 is a schematic cross-sectional view illustrating another example of a fan-out semiconductor package.

Referring to FIG. 13, also in a fan-out semiconductor package 300E according to another exemplary embodiment in the present disclosure, a first structure 100E and a second structure 200E may have a package-on-package form. However, the first structure 100E does not include a backside wiring layer 132 and backside vias 133. In addition, underbump metal layers 160 may be omitted. That is, openings exposing at least portions of a second wiring layer 112b of a first core member 110 may be formed in a first encapsulant 130, and electrical connection structures 170 may be formed in the openings of the first encapsulant 130 and be electrically connected to the exposed second wiring layer 112b. In this case, a process of manufacturing the fan-out semiconductor package 300E may further be simplified. A description of other configurations overlaps that described above, and is thus omitted. Meanwhile, a first core member 110 of the first structure 100E may have a form of the first core member 100 of the fan-out semiconductor packages 300B and 300C according to another exemplary embodiment described above.

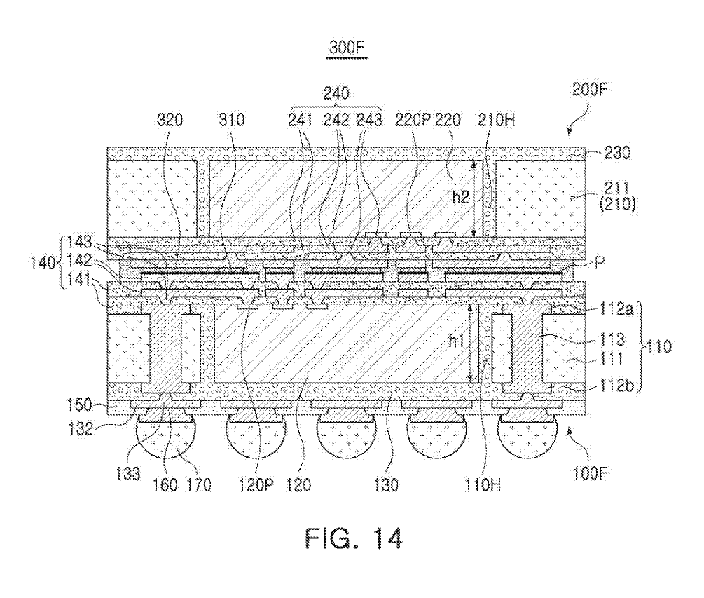

FIG. 14 is a schematic cross-sectional view illustrating another example of a fan-out semiconductor package.

Referring to FIG. 14, also in a fan-out semiconductor package 300F according to another exemplary embodiment in the present disclosure, a first structure 100F and a second structure 200F may have a package-on-package form. However, a first connection member 140 of the first structure 100F may include a plurality of first insulating layers 141, a plurality of first redistribution layers 142, and a plurality of first vias 143. In addition, a second connection member 240 of the second structure 200F may include a plurality of second insulating layers 241, a plurality of second redistribution layers 242, and a plurality of second vias 243. That is, the first and second connection members 140 and 240 may include larger numbers of insulating layers, redistribution layers, and vias. A description of other configurations overlaps that described above, and is thus omitted. Meanwhile, a first core member 110 of the first structure 100F may have a form of the first core member 100 of the fan-out semiconductor packages 300B and 300C according to another exemplary embodiment described above.

As set forth above, according to the exemplary embodiments in the present disclosure, a fan-out semiconductor package capable of being thinned and miniaturized in spite of using a plurality of semiconductor chips, reducing signal loss by shortening a connection distance between chips, and having improved reliability by securing sufficient rigidity may be provided.

While exemplary embodiments have been shown and described above, it will be apparent to those skilled in the art that modifications and variations could be made without departing from the scope of the present invention as defined by the appended claims.

What is claimed is:

1. A fan-out semiconductor package comprising:
a first structure including a first semiconductor chip having a first active surface having first connection pads disposed thereon and a first inactive surface opposing the first active surface, a first encapsulant encapsulating at least portions of the first semiconductor chip, and a first connection member disposed on the first active surface and including a first redistribution layer electrically connected to the first connection pads; and
a second structure including a second semiconductor chip having a second active surface having second connection pads disposed thereon and a second inactive surface opposing the second active surface, a second encapsulant encapsulating at least portions of the second semiconductor chip, and a second connection member disposed on the second active surface and including a second redistribution layer electrically connected to the second connection pads,
wherein the first and second structures are disposed so that the first and second active surfaces face each other, and
the first and second redistribution layers are connected to each other through a low melting point metal disposed between the first and second redistribution layers.

2. The fan-out semiconductor package of claim 1, wherein the low melting point metal includes tin (Sn) and silver (Ag).

3. The fan-out semiconductor package of claim 1, wherein a surface treatment layer is disposed on a surface of the first redistribution layer in contact with the low melting point metal.

4. The fan-out semiconductor package of claim 3, wherein the surface treatment layer includes one or more of palladium (Pd), nickel (Ni), and gold (Au).

5. The fan-out semiconductor package of claim 1, further comprising an underfill resin disposed between the first and second connection members and covering the first and second redistribution layers and the low melting point metal.

6. The fan-out semiconductor package of claim 5, wherein the underfill resin does not cover edges portions of an insulating layer of the first connection member on which the first redistribution layer is disposed, and
the underfill resin does not cover edges portions of an insulating layer of the second connection member on which the second redistribution layer is disposed.

7. The fan-out semiconductor package of claim 1, wherein the first structure further includes a first core member having a first through-hole,
the first semiconductor chip is disposed in the first through-hole, and
the first encapsulant fills at least portions of the first through-hole.

8. The fan-out semiconductor package of claim 7, wherein the first core member includes a plurality of wiring layers electrically connected to the first connection pads through the first redistribution layer and one layer or more vias electrically connecting the plurality of wiring layers to each other.

9. The fan-out semiconductor package of claim 8, wherein the first structure further includes a backside wiring layer disposed on the other surface of the first encapsulant opposing one surface of the first encapsulant on which the first connection member is disposed, backside vias penetrating through at least portions of the first encapsulant and connecting the backside wiring layer to at least one of the plurality of wiring layers of the first core member, a passivation layer disposed on the first encapsulant and having openings exposing at least portions of the backside wiring layer, underbump metal layers disposed in the openings of the passivation layer and connected to the exposed backside wiring layer, and electrical connection structures disposed on the passivation layer and connected to the underbump metal layers.

10. The fan-out semiconductor package of claim 8, wherein the first encapsulant is disposed on the other surface of the first core member opposing one surface of the first core member on which the first connection member is disposed, and has openings exposing at least portions of one of the plurality of wiring layers, and
the first structure further includes electrical connection structures disposed in the openings of the first encapsulant and connected to one of the plurality of wiring layers exposed by the openings.

11. The fan-out semiconductor package of claim 7, wherein the first core member includes a first insulating layer, a first wiring layer disposed on a first surface of the first insulating layer, a second wiring layer disposed on a second surface of the first insulating layer, and first vias penetrating through the first insulating layer and connecting the first and second wiring layers to each other, and
the first and second wiring layers are electrically connected to the first connection pads.

12. The fan-out semiconductor package of claim 11, wherein the first core member further includes a second insulating layer disposed on the first surface of the first insulating layer and covering the first wiring layer, a third wiring layer disposed on the second insulating layer, a third insulating layer disposed on the second surface of the first insulating layer and covering the second wiring layer, a fourth wiring layer disposed on the third insulating layer, second vias penetrating through the second insulating layer and connecting the first and third wiring layers to each other, and third vias penetrating through the third insulating layer and connecting the second and fourth wiring layers to each other, and
the third and fourth wiring layers are electrically connected to the first connection pads.

13. The fan-out semiconductor package of claim 7, wherein the first core member includes a first insulating layer in contact with the first connection member, a first wiring layer in contact with the first connection member and embedded in the first insulating layer, a second wiring layer disposed on the other surface of the first insulating layer opposing one surface of the first insulating layer in which the first wiring layer is embedded, a second insulating layer disposed on the first insulating layer and covering the second wiring layer, a third wiring layer disposed on the second insulating layer, first vias penetrating through the first insulating layer and connecting the first and second wiring layers to each other, and second vias penetrating through the second insulating layer and connecting the second and third wiring layers, and
the first to third wiring layers are electrically connected to the first connection pads.

14. The fan-out semiconductor package of claim 1, wherein the first semiconductor chip has a thickness greater than that of the second semiconductor chip.

15. The fan-out semiconductor package of claim 1, wherein the second semiconductor chip has a thickness greater than that of the first semiconductor chip.

16. The fan-out semiconductor package of claim 1, wherein the second structure further includes a second core member having a second through-hole,
the second semiconductor chip is disposed in the second through-hole, and
the second encapsulant fills at least portions of the second through-hole.

17. The fan-out semiconductor package of claim 1, wherein the first and second semiconductor chips are memory chips.

18. The fan-out semiconductor package of claim 1, wherein the first and second connection pads are in physical contact with first and second vias of the first and second connection members connected to the first and second redistribution layers.

19. The fan-out semiconductor package of claim 1, wherein the second encapsulant is in contact with an insulating layer of the first connection member on which the first redistribution layer is disposed.
